(19) United States
(12) Patent Application Publication
(10) Pub. No.: US 2026/0337747 A1
(43) Pub. Date: Oct. 29, 2026

(54) DEPOSITION MASK FOR OLED PIXEL DEPOSITION

(71) Applicant: LG INNOTEK CO., LTD., Seoul (KR)

(72) Inventors: Ki Young KWON, Seoul (KR); Kweon Jin LEE, Seoul (KR)

(21) Appl. No.: 19/115,363

(22) PCT Filed: Sep. 22, 2023
(86) PCT No.: PCT/KR2023/014560

§ 371 Date: Mar. 26, 2025

(30) Foreign Application Priority Data
Sep. 29, 2022 (KR) 10-2022-0124598

(51) Int. Cl. C23C 14/04; H10K 71/16

(52) U.S. Cl. CPC C23C 14/042; H10K 71/166

(57) ABSTRACT

A deposition mask according to an embodiment includes a metal plate having a first surface and a second surface opposite to the first surface, wherein the metal plate includes a deposition region and a non-deposition region, wherein the deposition region includes an effective region and an ineffective region, wherein a plurality of through holes are formed in the effective region, and formed by a small area hole formed on the first surface, a large area hole formed on the second surface, and a connecting portion connecting the small area hole and the large area hole, wherein the small area hole has a step height defined as a height of a region in which a width of the small area hole widens while extending from the connecting portion toward the first surface, and wherein the step height of the small area hole is Oum.

### TECHNICAL FIELD

The embodiment relates to a deposition mask for OLED pixel deposition.

### BACKGROUND ART

A display device is applied to various devices. For example, the display device is applied to a small device such as a smartphone or a tablet PC. Alternatively, the display device is applied to a large device such as a TV, a monitor, or a public display (PD). Recently, the demand for ultra-high definition (UHD) with a resolution of 500 PPI (Pixel Per Inch) or higher is increasing. Accordingly, display devices with high resolution are being applied to small devices and large devices.

The display device is classified into a LCD (Liquid Crystal Display) and an OLED (Organic Light Emitting Diode) depending on a driving method.

The LCD is a display device driven using liquid crystal. In addition, OLED is a display device driven using organic matter.

The OLED can achieve an infinite contrast ratio, has a response speed that is 1000 times faster than LCD, and has an excellent viewing angle. Accordingly, the OLED is attracting attention as a display device that can replace the LCD.

The OLED includes a light-emitting layer. The light-emitting layer includes an organic material. The organic material is deposited on a substrate by a deposition mask. The deposition mask may include an open mask (OM) or a fine metal mask (FMM). A deposition pattern corresponding to a pattern formed in the deposition mask is formed on the substrate. Accordingly, the deposition pattern can serve as a pixel.

The open mask is a thin plate that forms a deposition pattern only at a specific location when manufacturing an OLED. The open mask is used in a deposition process for forming a light-emitting layer thereon after a backplane is completed during the display manufacturing process. In other words, the open mask is a mask that does not have a covering region within a range in which the display operates in order to deposit an entire surface of the display. Therefore, the open mask is used when depositing a light-emitting layer with a light-emitting material of one color.

On the other hand, the fine metal mask is used to change a color of a sub-pixel of the light-emitting layer. Therefore, the fine metal mask includes an ultra-fine hole. A process using the fine metal mask must perform several stages of deposition. Therefore, the process requires precise alignment. Accordingly, the process using the fine metal mask is more difficult than the process using the open mask.

When the light-emitting layer of the OLED is deposited by the open mask, only one color light-emitting layer is formed. Therefore, a separate color filter (C/F) is required to implement various colors. On the other hand, when the fine metal mask is used, an RGB light-emitting layer can be formed. Therefore, a separate color filter is not required. In other words, a technology using the fine metal mask is more difficult. However, a method using the fine metal mask is more light-efficient as the method using the fine metal mask does not require a filter to block light, unlike the method using an open mask.

The fine metal mask is generally manufactured by an Invar alloy metal plate containing iron (Fe) and nickel (Ni). Through holes are formed on one surface and other surface of the metal plate and penetrates the one surface and the other surface. The through holes are formed at positions corresponding to pixel patterns. Accordingly, red, green, and blue organic materials can pass through the through holes of the metal plate and be deposited on the substrate. By this, pixel patterns can be formed on the substrate.

Meanwhile, the fine metal mask includes a small area hole formed on one surface of the metal plate and a large area hole formed on the other surface of the metal plate. The small area hole and the large area hole are connected by a connecting portion, thereby forming the through hole.

The organic material is sprayed toward the fine metal mask. The organic material is deposited on the deposition substrate with the large area hole as an inlet and the small area hole as an outlet.

In detail, a plurality of fine metal masks in a strip shape are arranged on the deposition substrate. The organic material moves to the small area hole through the large area hole.

At this time, the deposition pattern formed on the deposition substrate may form a shadow region according to a shape of the small area hole. The shadow region is a pattern formed outside the deposition pattern. Adjacent patterns may overlap each other due to the shadow region.

As a result, a deposition quality and deposition reliability of the deposition mask may decrease.

Therefore, a deposition mask having a new structure that can solve the above problems is required.

### DISCLOSURE

### Technical Problem

The invention provides a deposition mask having improved deposition reliability and deposition quality.

### Technical Solution

A deposition mask according to an embodiment includes a metal plate having a first surface and a second surface opposite to the first surface, wherein the metal plate includes a deposition region and a non-deposition region, wherein the deposition region includes an effective region and an ineffective region, wherein a plurality of through holes are formed in the effective region, and formed by a small area hole formed on the first surface, a large area hole formed on the second surface, and a connecting portion connecting the small area hole and the large area hole, wherein the small area hole has a step height defined as a height of a region in which a width of the small area hole widens while extending from the connecting portion toward the first surface, and wherein the step height of the small area hole is Oum.

### Advantageous Effects

The deposition mask according to the embodiment includes a small area hole. The small area hole has a step height of a set size.

The step height of the small area hole may be 0. Accordingly, a size of a shadow region is reduced. Accordingly, adjacent deposition patterns can be prevented from overlapping.

Alternatively, the step height of the small area hole may be greater than 0 and less than or equal to 5 μm. Accordingly, a size of the shadow region is reduced. In addition, an amount of an organic material disposed on a first surface of the deposition mask is minimized. Accordingly, a separation of the deposition mask and a deposition substrate becomes easy.

In addition, the deposition mask according to the embodiment includes a protrusion. The protrusion is disposed on the first surface on which the small area hole is formed.

Accordingly, when an organic material exists between the first surface and the deposition substrate, the deposition mask and the deposition substrate are easily separated by the protrusion.

Therefore, when the deposition mask is separated, the deposition mask can be prevented from being damaged.

In addition, a surface roughness of the first surface is smaller than a surface roughness of the second surface.

Accordingly, an amount of an organic material deposited on the first surface is reduced. Therefore, the deposition mask and the deposition substrate are easily separated by the protrusion.

Therefore, when separating the deposition mask, the deposition mask can be prevented from being damaged.

In addition, a gap between the deposition mask and the deposition substrate can be prevented. Therefore, a size and a shape of the deposition pattern become uniform.

Therefore, a deposition quality of the deposition mask is improved.

### DESCRIPTION OF DRAWINGS

FIG. 1 is a drawing illustrating a combination of a deposition mask and a frame according to an embodiment.

FIG. 2 is a cross-sectional view of an organic deposition device including a deposition mask according to an embodiment.

FIG. 3 is a drawing illustrating that a deposition pattern is formed on a deposition substrate by a through hole of a deposition mask according to an embodiment.

FIGS. 4 (a) and (b) are drawings for explaining a difference in a deposition pattern according to a step height of a deposition mask according to an embodiment.

FIG. 5 is a plan view of a deposition mask according to an embodiment.

FIG. 6 and FIG. 7 are cross-sectional views taken along region C-C′ of FIG. 5.

FIG. 8 is a drawing for explaining a change in a step height according to an electrolytic polishing of a small area hole of a deposition mask according to an embodiment.

FIG. 9 is a cross-sectional view taken along region D-D′ region of FIG. 5.

FIG. 10 is a drawing for explaining an effect of a protrusion of a deposition mask according to an embodiment.

FIG. 11 is a drawing for explaining a surface roughness of a deposition mask according to an embodiment.

FIG. 12 is a drawing for explaining a relationship between a surface roughness and a current density of a deposition mask according to an embodiment.

FIGS. 13 (a) and (b) are photographs of a first surface and a second surface of a deposition mask according to an embodiment.

### BEST MODE

Hereinafter, embodiments will be described in detail with reference to the accompanying drawings. However, the spirit and scope of the present invention is not limited to a part of the embodiments described, and may be implemented in various other forms, and within the spirit and scope of the present invention, one or more of the elements of the embodiments may be selectively combined and replaced. In addition, unless expressly otherwise defined and described, the terms used in the embodiments of the present invention (including technical and scientific terms) may be construed the same meaning as commonly understood by one of ordinary skill in the art to which this invention belongs, and the terms such as those defined in commonly used dictionaries may be interpreted as having a meaning that is consistent with their meaning in the context of the relevant art.

Further, the terms used in the embodiments of the present invention are for describing the embodiments and are not intended to limit the present invention. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present invention, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “connected” to another element, it may include not only when the element is directly “connected” to, “coupled” to, or “connected” to other elements, but also when the element is “connected”, “coupled”, or “connected” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements.

Furthermore, when expressed as “on (over)” or “under (below)”, it may include not only the upper direction but also the lower direction based on one element.

A deposition mask described below is a fine metal mask (FMM) that can form an RGB pixel pattern on a deposition substrate by depositing organic materials such as red, green, and blue on the deposition substrate, and a following description does not apply to an open mask (OM).

In the description below, a first direction is a length direction of the deposition mask. In addition, a second direction is a width direction of the deposition mask.

In the description below, a height of a small area hole is a height from a connecting portion to a first surface. In addition, a step height of the small area hole is a height of a region where a width of the small area hole widens in a direction extending from the connecting portion to the first surface.

Hereinafter, a deposition mask according to an embodiment will be described with reference to the drawings.

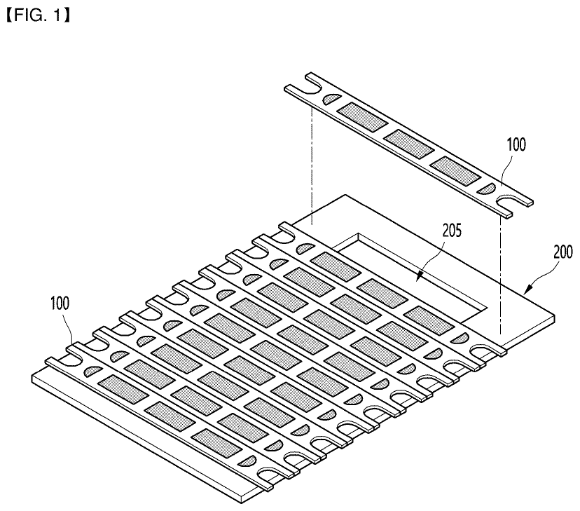

FIGS. 1 to 3 are drawings for explaining a process of depositing an organic material on a deposition substrate 300 using a deposition mask 100 according to an embodiment.

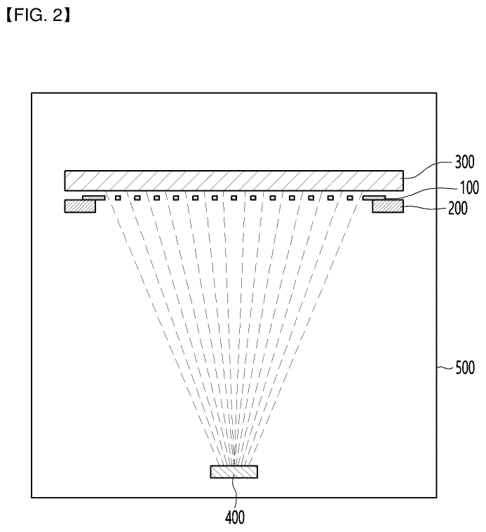

Referring to FIGS. 1 and 2, an organic material deposition device includes a deposition mask 100, a mask frame 200, a deposition substrate 300, an organic material deposition container 400, and a vacuum chamber 500.

The deposition mask 100 includes a metal. For example, the deposition mask includes iron (Fe) and nickel (Ni). In detail, the deposition mask includes an invar alloy including iron (Fe) and nickel (Ni).

The deposition mask 100 includes a plurality of through holes TH. The through holes are arranged in an effective portion. The through holes are arranged to correspond to a pixel pattern to be formed on a deposition substrate.

The mask frame 200 includes an opening 205. The plurality of through holes are arranged on a region corresponding to the opening 205. Accordingly, an organic material supplied to the organic material deposition container 400 is deposited on the deposition substrate 300. The deposition mask 100 is arranged and fixed on the mask frame 200. For example, the deposition mask 100 is tensioned with a constant tensile force. In addition, the deposition mask 100 is welded and fixed on the mask frame 200.

For example, the non-effective region of the deposition mask 100 is welded. By this, the deposition mask 100 is fixed on the mask frame 200. Then, a portion protruding outwardly of the mask frame 200 is cut and removed.

The mask frame 200 includes a metal having high rigidity. By this, a deformation of the mask frame is reduced during a welding process.

The deposition substrate 300 is a substrate used when manufacturing a display device. For example, an OLED pixel pattern is formed on the deposition substrate 300. In order to form pixels, which are three primary colors of light, organic patterns of red, green, and blue are formed on the deposition substrate 300. That is, an RGB pattern is formed on the deposition substrate 300.

The organic deposition container 400 is a crucible. An organic material is disposed inside the crucible. The organic material deposition container 400 moves within the vacuum chamber 500. That is, the organic material deposition container 400 moves in one direction within the vacuum chamber 500. For example, the organic material deposition container 400 moves in a width direction of the deposition mask 100 within the vacuum chamber 500.

A heat source and/or current is supplied to the organic material deposition container 400. Accordingly, the organic material is deposited on the deposition substrate 300.

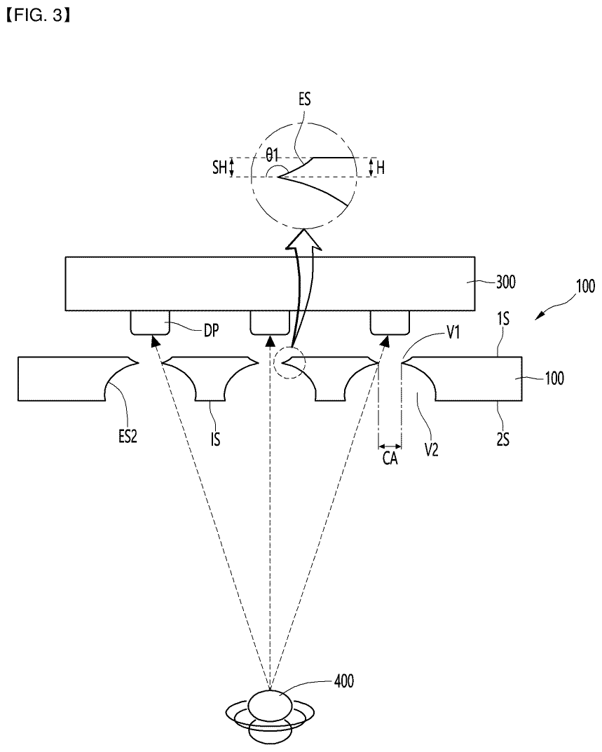

Referring to FIG. 3, the deposition mask 100 includes a metal plate 10. The metal plate includes a first surface 1S and a second surface 2S. The first surface 1S and the second surface 2S are opposite surfaces.

The first surface 1S includes a small area hole V1. The second surface 2S includes a large area hole V2. For example, a plurality of small area holes V1 and a plurality of large area holes V2 are formed on the first surface 1S and the second surface 2S, respectively.

In addition, the deposition mask 100 includes a through hole TH. The through hole TH is formed by a connecting portion CA connecting boundaries of the small area hole V1 and the large area hole V2.

A width of the large area hole V2 is larger than a width of the small area hole V1. The width of the small area hole V1 is measured on the first surface 1S of the deposition mask 100. The width of the large area hole V2 is measured on the second surface 2S of the deposition mask 100.

In addition, a width of the connecting portion CA has a set size. In detail, the width of the connection portion CA may be 15 μm to 33 μm. In more detail, the width of the connection portion CA may be 19 μm to 33 μm. In more detail, the width of the connection portion CA may be 20 μm to 27 μm. If the width of the connection portion CA exceeds 33 μm, it is difficult to implement a resolution of 500 PPI or higher. In addition, if the width of the connection portion CA is less than 15 μm, a defect may occur during a deposition process.

The small area hole V1 faces the deposition substrate 300. The small area hole V1 is arranged close to the deposition substrate 300. Accordingly, the small area hole V1 has a shape corresponding to a deposition pattern DP.

The large area hole V2 faces the organic material deposition container 400. Accordingly, the organic material supplied from the organic material deposition container 400 can be accommodated in a wide width by the large area hole V2. In addition, a fine pattern can be quickly formed on the deposition substrate 300 through the small area hole V1.

Accordingly, the organic material accommodated by the large area hole V1 is deposited on the deposition substrate 300 by the small area hole V1. Accordingly, one of the red, green, or blue pixel patterns is formed on the deposition substrate 300. Subsequently, the above process is repeated. Accordingly, all of the red, green, or blue pixel patterns are formed on the deposition substrate 300.

Referring to FIG. 3, the small area hole V1 has a step height SH. The step height SH is a height of a region where a width of the small area hole V1 widens in a direction extending from the connecting portion to the first surface 1S. In addition, the step height SH is a region where an angle (θ1) formed by the connecting portion CA and an inner surface ES of the small area hole V1 is an obtuse angle or a right angle.

A boundary region of the small area hole V1 and the first surface 1S may have a curvature. In addition, the boundary region of the large area hole V2 and the second surface 2S may have a curvature. A region where the width of the small area hole widens due to the curvature is excluded from the step height SH. That is, a corner region M of FIG. 7 is excluded from the step height SH.

The corner region M is a tolerance that occurs when manufacturing a deposition mask. For example, when forming the large area hole, a corner where the small area hole and the first surface meet may have a small curvature formed by an etching solution. Alternatively, a corner where an inner surface of the through hole and the first surface meet may have a curvature formed during an electropolishing process. Alternatively, a corner where an inner surface of the through hole and the second surface meet may have a curvature formed during the electropolishing process. The corner region may be a region where the curvature is formed.

The height H of the small area hole V1 is a height from the connecting portion CA to the first surface 1S.

Therefore, when a width of the small area hole V1 widens from the connecting portion in a direction of the first surface 1S, a step height SH of the small area hole and the height H may be same or similar.

Alternatively, when an angle (θ1) formed between the connecting portion CA and the inner surface ES of the small area hole V1 is an obtuse angle, the step height SH and the height H of the small area hole may be the same or similar.

On the other hand, when the width of the small area hole V1 narrows in the direction of the first surface 1S from the connecting portion, the step height SH and the height H of the small area hole may be different.

Alternatively, when the angle (θ1) formed between the connecting portion CA and the inner surface ES of the small area hole V1 is an acute angle or a right angle, the step height SH and the height H of the small area hole may be different.

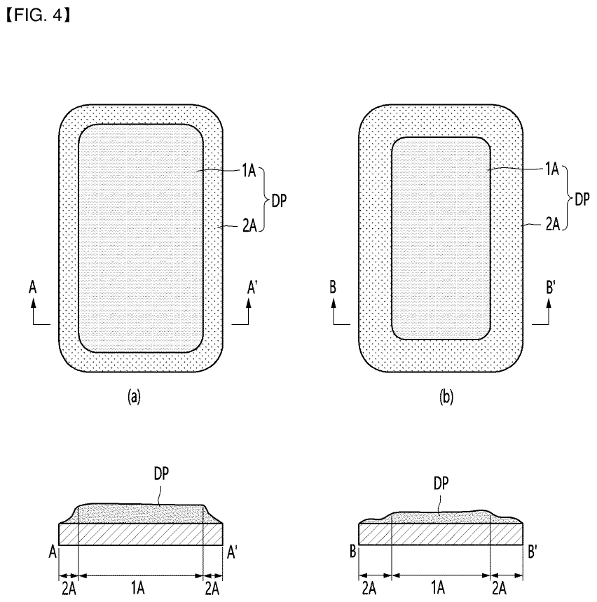

FIG. 4 is a drawing for explaining a difference in a deposition pattern according to a step height SH of a small area hole V1.

FIG. 4(a) is a drawing showing a deposition pattern DP when a step height SH of the small area hole V1 is relatively small. FIG. 4(b) is a drawing showing a deposition pattern DP when a step height SH of the small area hole V1 is relatively large.

The deposition pattern DP may include a first region 1A and a second region 2A. A width of the first region 1A varies depending on a width of the connecting portion CA. a width of the second region 2A varies depending on the step height SH.

A thickness of the first region 1A may be uniform. In addition, a thickness of the second region 2A may not be uniform.

That is, the first region 1A and the second region 2A may be deposition patterns arranged on the deposition substrate 300. In addition, the second region 2A is a region where the organic material spreads in the deposition pattern DP. That is, the second region 2A is a shadow region. The width of the second region 2A may increase as the step height SH increases. If the width of the second region 2A increases beyond the set range, adjacent deposition patterns may overlap each other. Accordingly, there is a problem that the deposition quality of the deposition mask decreases.

Hereinafter, a deposition mask that can solve the above problem will be described.

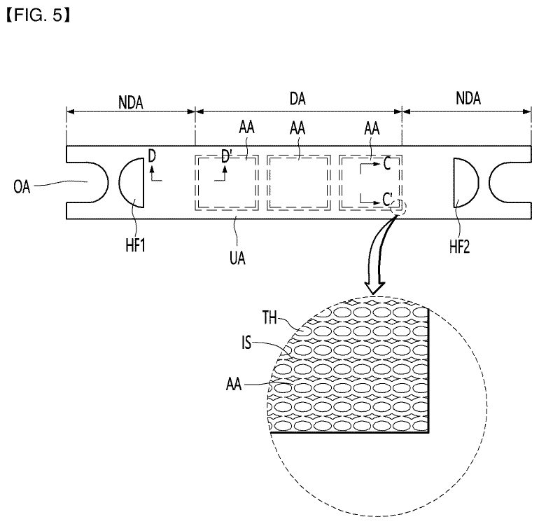

Referring to FIGS. 5 to 13, the deposition mask 100 includes a deposition region DA and a non-deposition region NDA.

A deposition region DA is a region for forming a deposition pattern. The deposition region DA includes an effective region AA and an ineffective region UA. The effective region AA is a region where a through hole TH through which the organic material passes is formed. In addition, the ineffective region UA is a region where the through hole TH is not formed.

In the drawing, the effective region AA is illustrated as a square shape. However, the embodiment is not limited thereto. The effective region AA may have a rectangular shape or a circular shape.

The effective region AA includes a plurality of effective regions. The plurality of effective regions are spaced apart in a first direction.

The deposition region DA is a region from a point where a first effective region starts to a point where a last effective region ends in a first direction.

The ineffective region UA is a deposition region other than the effective region AA.

The non-deposition region NDA is a region that does not participate in deposition. The non-deposition region NDA includes a frame fixing region FA1 and FA2. The frame fixing region is a region for fixing the deposition mask 100 to the mask frame 200. In addition, the non-deposition region NDA may include at least one of a half-etched portion HF and an open portion OA. The half-etched portion HF is formed by partially etching the metal plate 10. The open portion OA is formed by completely etching the metal plate 10.

Residual stress generated when the deposition mask 100 is tensioned is dispersed by the half-etched portion HF. Accordingly, a waviness of the deposition mask is reduced.

In addition, a jig such as a clamp used when tensioning the deposition mask 100 is fixed to the open portion OP.

A plurality of through holes TH are formed inside the effective region AA. A plurality of island portions IS are arranged between the plurality of through holes TH. The island portion IS is a surface where the first surface 1S or the second surface 2S is not etched. The island portion IS connects adjacent ribs RB. The rib RB is a region where inner surfaces of adjacent through holes meet. The rib RB is a region where the metal plate 10 is partially etched.

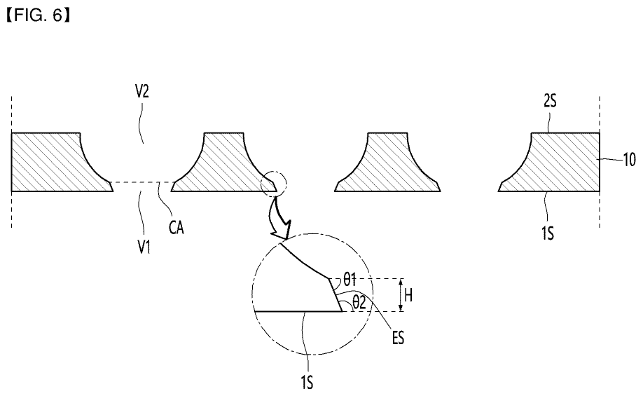

Referring to FIGS. 6 and 7, the metal plate 10 includes a first surface 1S and a second surface 2S opposite to the first surface 1S.

A plurality of small area holes V1 are formed on the first surface 1S. A large area hole V2 is formed on the second surface 2S.

The small area hole V1 and the large area hole V2 are connected by the connecting portion CA. Accordingly, the through hole TH is formed.

The step height SH of the small area hole V1 may have a set range.

Referring to FIG. 6, the step height SH of the small area hole V1 may be 0 μm. In detail, a width of the small area hole V1 may be narrowed from the connecting portion CA toward the first surface 1S. In addition, the step height SH may be 0 μm. That is, the small area hole V1 may have a height H within a set range, and the step height SH may be 0 μm.

That is, the angle (θ1) formed by the inner surface ES of the small area hole V1 and the connecting portion CA may be an acute angle or a right angle. In addition, the angle (θ2) formed by the inner surface ES of the small area hole V1 and the first surface 1S may be an obtuse angle or a right angle. In addition, the step height SH may be 0.

Therefore, a shadow region of the deposition pattern is reduced. In detail, the width of the small area hole V1 is narrowed from the connecting portion CA toward the first surface 1S. Therefore, when the organic material is deposited on the deposition substrate 300, a region where the organic material spreads in an outer direction is reduced.

Therefore, overlapping of the deposition pattern according to the shadow region can be prevented. Therefore, the deposition mask has improved deposition reliability.

Referring to FIG. 7, the small area hole V1 may have a step height SH of a set range. In detail, the step height SH of the small area hole V1 may be 5 μm or less. More specifically, the step height SH of the small area hole V1) may be greater than Oum and smaller than or equal to than 5 μm, and may be 0.01 μm to 3 μm, 0.1 μm to 2.5 μm, or 1 μm to 2.2 μm.

The step height SH of the small area hole V1 may be controlled by a process of etching or polishing the small area hole V1. For example, the step height SH may be controlled by selectively wet etching or dry etching the small area hole V1. Alternatively, the step height SH may be controlled by electropolishing, chemical polishing, mechanical polishing, or chemical mechanical polishing (CMP) of the small area hole V1.

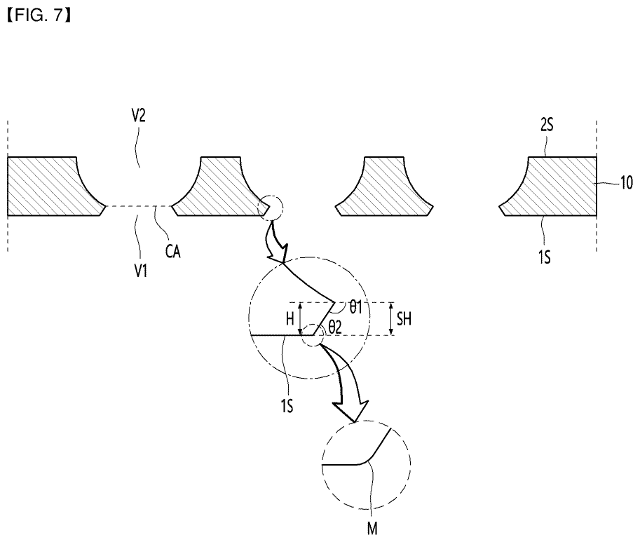

For example, the step height SH can be controlled by electropolishing. The step height SH can be changed according to a size and an application time of the current applied during the electropolishing process. In detail, referring to FIG. 8, a step height SH can be greater than Oum and smaller than or equal to 5 μm depending on the size and application time of the current. That is, the step height SH can decrease as the time and/or the size of the current increases.

In detail, a width of the small area hole V1 widens from the connecting portion CA toward the first surface 1S, and the step height SH can have the above range.

That is, an angle formed by the inner surface ES of the small area hole V1 and the connecting portion CA can be an obtuse angle. In addition, the angle (θ2) formed by the inner surface ES of the small area hole V1 and the first surface 1S can be an acute angle. In addition, the step height SH may have the above range.

In addition, the angle (θ2) formed by the inner surface ES of the small area hole V1 and the first surface 1S may be 35° to 55°.

When the step height SH exceeds 5 μm, the shadow region may increase. Accordingly, adjacent deposition patterns may overlap. Accordingly, the deposition reliability of the deposition mask is reduced.

Therefore, the step height SH of the small area hole V1 is controlled to the above range. Accordingly, when the organic material is deposited on the deposition substrate 300, a region where the organic material spreads in the outer direction is reduced.

Accordingly, the overlapping of deposition patterns according to the shadow region can be prevented. Accordingly, the deposition mask has improved deposition reliability.

In addition, the small area hole has the set step height. Accordingly, the deposition of the organic material on the first surface adjacent to the small area hole is minimized. Therefore, the separation of the deposition mask and the deposition substrate becomes easy.

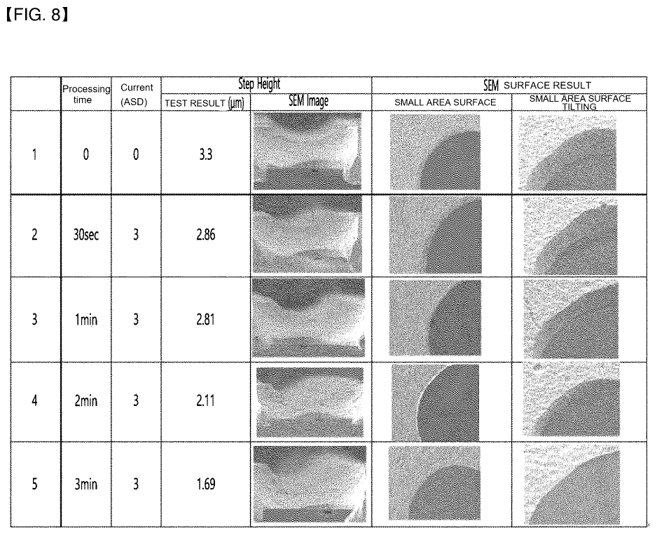

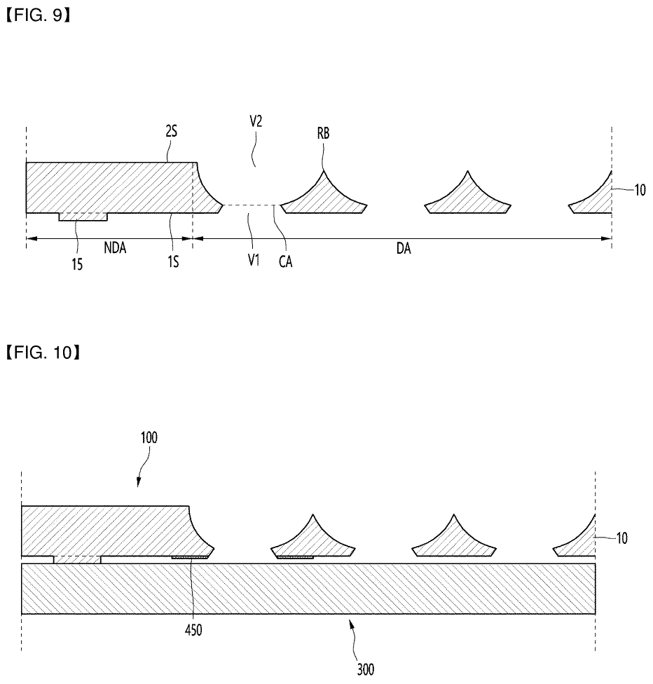

Referring to FIGS. 9 and 10, the deposition mask 100 may include at least one protrusion 15.

The protrusion 15 is disposed in the non-deposition region NDA. The protrusion 15 is disposed on the first surface 1S.

The protrusion 15 and the metal plate 10 may include a same material. For example, the protrusion 15 may be formed integrally with the metal plate 10. The embodiment is not limited thereto. The protrusion 15 may include a different material from the metal plate 10. In addition, the protrusion 15 may be separated from the metal plate 10.

For example, the protrusion 15 and the metal plate 10 may include a same material. In addition, the protrusion 15 may be formed together when the through hole is formed. In detail, after forming the small area hole and the large area hole, the first surface may be additionally etched in order to control the step height. For example, the first surface may be additionally etched by an electrolytic polishing process.

At this time, a mask is placed in a region where the protrusion is formed. Accordingly, the region where the mask is placed is not etched, so the protrusion is formed on the first surface.

The deposition mask 100 and the deposition substrate 300 are easily separated by the protrusion.

Referring to FIG. 10, the small area hole V1 may have a step height SH. The organic material 450 may flow to a region adjacent to the small area hole V1. Accordingly, the organic material 450 may be deposited on the first surface 1S. The deposition mask 100 and the deposition substrate 300 can be bonded by the organic material deposited on the first surface. Accordingly, the separation of the deposition mask 100 and the deposition substrate 300 becomes difficult. In addition, when the deposition mask 100 and the deposition substrate 300 are separated, the deposition mask 100 can be damaged.

Therefore, at least one protrusion is arranged on the first surface. Therefore, the above problem can be solved. That is, when the organic material is deposited on the first surface 1S, the deposition mask 100 and the deposition substrate 300 are easily separated by the protrusion.

In FIG. 9 and FIG. 10, the protrusion 15 is illustrated as being arranged in the non-deposition region. However, the embodiment is not limited thereto. The protrusion 15 can be arranged in the deposition region. Alternatively, the protrusion 15 may be disposed in both the non-deposition region and the deposition region.

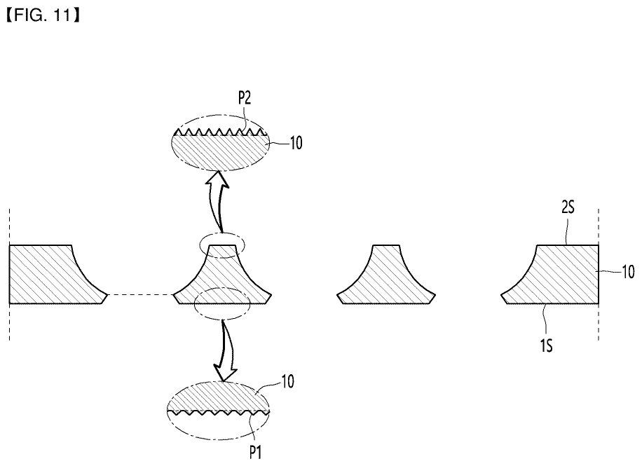

Referring to FIG. 11, the first surface 1S and the second surface 2S may include patterns. In detail, the first surface 1S includes a plurality of first patterns P1. The second surface 2S includes a plurality of second patterns P2.

Accordingly, the first surface 1S and the second surface 2S have surface roughnesses within a set range. The first surface 1S has a first surface roughness. In addition, the second surface 2S has a second surface roughness.

The first surface roughness and the second surface roughness may be different. In detail, the first surface roughness may be smaller than the second surface roughness.

The first surface roughness may have an arithmetic mean roughness (Ra) of 30 nm to 160 nm. In detail, the first surface roughness may have an arithmetic mean roughness (Ra) of 35 nm to 80 nm or 35 nm to 75 nm.

In addition, the first surface roughness may have a 10-point average roughness (Rz) of 0.5 μm to 1.7 μm. In detail, the first surface roughness may have a 10-point average roughness (Rz) of 0.5 μm to 1.5 μm or 0.5 μm to 1.1 μm.

The first surface roughness may vary depending on the current density during the electropolishing process. In detail, when a magnitude of the current applied during the electropolishing process and/or a current application time increase, the magnitude of the first surface roughness decreases.

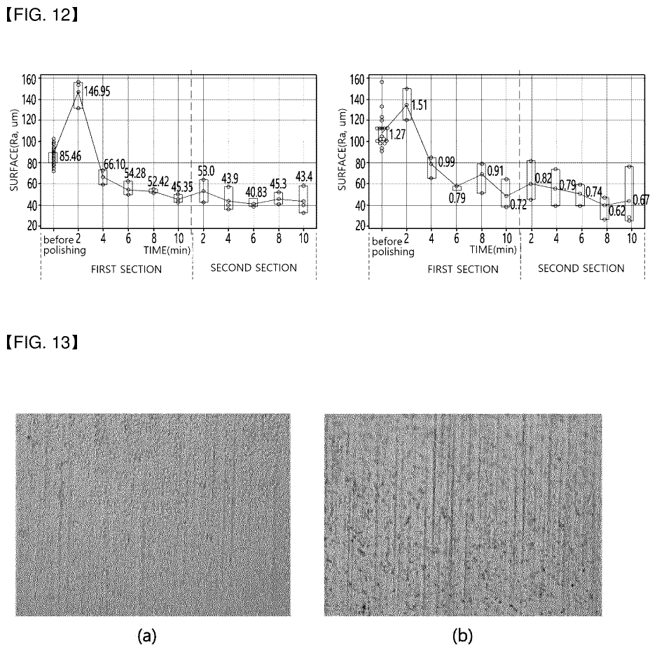

In detail, referring to FIG. 12, in a second section where a current density is twice that of a first section, the arithmetic mean roughness (Ra) and the 10-point average roughness (Rz) of the first surface 1S are reduced.

The first surface roughness has the above range. In addition, the first surface roughness is smaller than the second surface roughness. That is, referring to FIG. 13, the first surface roughness of the first surface ((a) of FIG. 13) is smaller than the second surface roughness of the second surface ((b) of FIG. 13).

As described above, after forming the small area hole and the large area hole, the first surface is additionally etched or polished. Accordingly, the surface roughness of the first surface 1S becomes smaller than the surface roughness of the second surface 2S.

By reducing the surface roughness of the first surface, the deposition mask 100 and the deposition substrate 300 are easily separated.

The small area hole V1 may have a step height SH. The organic material 450 may flow to a region adjacent to the small area hole V1. Accordingly, the organic material 450 may be deposited on the first surface 1S. The deposition mask 100 and the deposition substrate 300 may be bonded by the organic material deposited on the first surface. Accordingly, the separation of the deposition mask 100 and the deposition substrate 300 becomes difficult. In addition, when the deposition mask 100 and the deposition substrate 300 are separated, the deposition mask 100 may be damaged.

Therefore, the surface roughness of the first surface is reduced. Accordingly, the amount of the organic material deposited on the first surface 1S may be reduced. Accordingly, the separation of the deposition mask 100 and the deposition substrate 300 becomes easy.

In addition, a gap between the deposition mask 100 and the deposition substrate 300 is minimized.

Accordingly, the distance between the deposition mask 100 and the deposition substrate 300 becomes uniform. Accordingly, the shape or size of the deposition pattern becomes uniform, thereby improving the deposition quality.

The deposition mask according to the embodiment includes a small area hole. The small area hole has a step height of a set size.

The step height of the small area hole may be 0. Accordingly, a size of a shadow region is reduced. Accordingly, adjacent deposition patterns can be prevented from overlapping.

Alternatively, the step height of the small area hole may be greater than 0 and less than or equal to 5 μm. Accordingly, a size of the shadow region is reduced. In addition, an amount of an organic material disposed on a first surface of the deposition mask is minimized. Accordingly, a separation of the deposition mask and a deposition substrate becomes easy.

In addition, the deposition mask according to the embodiment includes a protrusion. The protrusion is disposed on the first surface on which the small area hole is formed.

Accordingly, when an organic material exists between the first surface and the deposition substrate, the deposition mask and the deposition substrate are easily separated by the protrusion.

Therefore, when the deposition mask is separated, the deposition mask can be prevented from being damaged.

In addition, a surface roughness of the first surface is smaller than a surface roughness of the second surface.

Accordingly, an amount of an organic material deposited on the first surface is reduced. Therefore, the deposition mask and the deposition substrate are easily separated by the protrusion.

Therefore, when separating the deposition mask, the deposition mask can be prevented from being damaged.

In addition, a gap between the deposition mask and the deposition substrate can be prevented. Therefore, a size and a shape of the deposition pattern become uniform.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1. A deposition mask comprising:
a metal plate having a first surface and a second surface opposite to the first surface,
wherein the metal plate includes a deposition region and a non-deposition region,
wherein the deposition region includes an effective region and an ineffective region,
wherein a plurality of through holes are formed in the effective region, and includes a small area hole formed on the first surface, a large area hole formed on the second surface, and a connecting portion connecting the small area hole and the large area hole, and
wherein the small area hole does not have a region in which a width in a horizontal direction increases from the connecting portion toward the first surface.

2. The deposition mask of claim 1, wherein an angle formed by the connecting portion and an inner surface of the small area hole is an acute angle or a right angle.

3. The deposition mask of claim 1, wherein the width in the horizontal direction of the small area hole decreases from the connecting portion toward the first surface.

4. The deposition mask of claim 3, wherein an arithmetic mean roughness (Ra) of an inner surface of the small area hole of 30 nm to 160 nm.

5. The deposition mask of claim, further comprising:
a protrusion arranged on the first surface.

6. The deposition mask of claim 5, wherein the protrusion is arranged on at least one region of the deposition region and the non-deposition region.

7. The deposition mask of claim 5, wherein the protrusion is formed integrally with the metal plate.

8. The deposition mask of claim 1, wherein a surface roughness of the first surface and a surface roughness of the second surface are different.

9. The deposition mask of claim 8, wherein the surface roughness of the first surface is smaller than the surface roughness of the second surface.

10. The deposition mask of claim 9, wherein the surface roughness of the first surface roughness has an arithmetic mean roughness (Ra) of 30 nm to 160 nm or a ten-point average roughness of 0.5 μm to 1.7 μm.

11. The deposition mask of claim 3, wherein a width in the horizontal direction of the large area hole decreases from the second surface toward the connecting portion.

12. The deposition mask of claim 11, wherein an inner surface of the large area hole and an inner surface of the small area hole are inclined in a same direction from the first surface to the second surface.

13. The deposition mask of claim 12, wherein a curvature of the inner surface of the large area hole and a curvature of the inner surface of the small area hole are different from each other.
